(19) United States
(12) Patent Application Publication
(10) Pub. No.: US 2012/0101753 A1
(43) Pub. Date: Apr. 26, 2012

(54) ADAPTIVE SLOWLY-VARYING CURRENT DETECTION

(75) Inventors: Jian Lin, Beverly Hills, MI (US); Xidong Tang, Sterling Heights, MI (US); Brian J. Koch, Berkley, MI (US)

(73) Assignee: GM GLOBAL TECHNOLOGY OPERATIONS, INC., DETROIT, MI (US)

(21) Appl. No.: 12/908,669

(22) Filed: Oct. 20, 2010

(51) Int. Cl. G01R 31/36

(52) U.S. Cl. 702/63

(57) ABSTRACT

A system and method for determining whether an onboard estimation process, such as a recursive least squares regression process, can effectively calculate the state-of-charge of a battery. The method includes defining a current sample time and a previous sample time and measuring the battery current. The method then calculates a variation moving average of the measured current and an index of current change rate determined by averaging the absolute value of the current variation moving average using the measured current and calculated moving averages from the previous sample time. The method then determines if the current change index is greater than a predetermined threshold, and if so, the estimate of the battery state-of-charge resulting from the onboard estimation process is valid.

### BACKGROUND OF THE INVENTION

1. Field of the Invention

This invention relates generally to a system and method for estimating battery state-of-charge (SOC) and, more particularly, to a system and method for estimating battery SOC that includes calculating a current change index to determine whether the battery current contains enough excitation so that an onboard real time estimation algorithm, such as a recursive least squares (RLS) regression algorithm, can provide an accurate estimate of the SOC.

2. Discussion of the Related Art

Electric vehicles are becoming more and more prevalent. These vehicles include hybrid vehicles, such as the extended range electric vehicles (EREV) that combines a battery and a main power source, such as an internal combustion engine, fuel cell system, etc., and electric only vehicles, such as the battery electric vehicles (BEV). All of these types of electric vehicles employ a high voltage battery that includes a number of battery cells. These batteries can be different battery types, such as lithium-ion, nickel metal hydride, lead acid, etc. A typical high voltage battery for an electric vehicle may include 196 battery cells providing about 400 volts. The battery can include individual battery modules where each battery module may include a certain number of battery cells, such as twelve cells. The individual battery cells may be electrically coupled in series, or a series of cells may be electrically coupled in parallel, where a number of cells in the module are connected in series and each module is electrically coupled to the other modules in parallel. Different vehicle designs include different battery designs that employ various trade-offs and advantages for a particular application.

Batteries play an important role in powering electrical vehicles and hybrid vehicles. The effectiveness of battery control and power management is essential to vehicle performance, fuel economy, battery life and passenger comfort. For battery control and power management, two states of the battery, namely, state-of-charge (SOC) and battery power, need to be predicted, or estimated, and monitored in real time because they are not measurable during vehicle operation. Battery state-of-charge and battery power can be estimated using an equivalent circuit model of the battery that defines the battery open circuit voltage (OCV), battery ohmic resistance and an RC pair including a resistance and a capacitance using the battery terminal voltage and current. Therefore, both battery states have to be derived from battery parameters estimated from the battery terminal voltage and current. A few battery state estimation algorithms have been developed in the art using different methodologies and some have been implemented in vehicles.

It is well known that battery dynamics are generally non-linear and highly dependent on battery operating conditions. However, for on-board battery parameter estimation, a linear model that has a few frequency modes can be used to approximate a battery's dominant dynamics for a specific application, such as power prediction or SOC estimation. The reason for this is mainly due to limited computational power and memory available for on-board applications. In fact, even if there was unlimited computational power and memory, an accurate estimation of all battery parameters in a complex model with as many frequency modes as possible cannot be guaranteed because the excitation of signals, normally battery terminal voltage and terminal current, is limited. Therefore, it is neither practical nor necessary to cover all frequency modes in one model as long as the estimation error caused by model uncertainties is within an acceptable range for a specific application.

In order to minimize the memory and computational cost, a simple battery model is preferred. On the other hand, different applications need to be characterized by different frequency modes. For instance, the feature frequency to characterize the high frequency resistance of a battery is much higher than the feature frequency that characterizes a change in battery power. A simple model with limited frequency modes inevitably introduces errors and uncertainties because it cannot fully cover all feature frequencies for various applications.

U.S. patent application Ser. No. 11/867,497, filed Oct. 4, 2007, now published as Publication No. U.S. 2009/0091299, titled Dynamically Adaptive Method For Determining The State of Charge of a Battery, assigned to the assignee of this invention and herein incorporated by reference, discloses a method for determining battery state-of-charge and battery power using four battery parameters, namely, the battery open circuit voltage (OCV), ohmic resistance, and the resistance and capacitance of an RC pair.

One known technique for estimating battery SOC is to use a recursive least squares (RLS) regression algorithm to estimate the battery open circuit voltage V_{oc} from the measured battery current I and battery voltage V. Linear equations are used in RLS algorithm that employ matrices which require independent rows of data in order to solve the equations. This data is determined from the battery current I which needs to be changing at different rates from one sample time to the next in order for there to be a solution to the equations. In other words, the RLS algorithm will not be effective to determine battery SOC if the current is not changing significantly over time because the equations in the RLS calculations are the same, or nearly the same, from one time sample to the next. Stated another way, the quality of the regressed open circuit voltage V_{oc} is a function of input parameter excitation, where more excitation produces a better open circuit voltage output. A lack of excitation must be detected so that the poor-quality output is not used in the SOC estimation. Known techniques for determining if the current is changing at enough different rates include monitoring the regression math for a divide-by-zero scenario, however the detection was sometimes too slow to prevent instability and loss of SOC accuracy under all conditions.

When the battery current is changing only minimally, the values in the matrices of the linear equations do provide a solution, but that solution is not guaranteed to be correct so that the accuracy of the calculations is not acceptable. Thus, the resulting battery SOC estimation cannot be accurately determined. It is typically difficult to determine what thresholds should be used for an acceptable battery current change rate, below which the battery SOC estimation will not be accurate.

When the RLS algorithm is not acceptable to give an accurate battery SOC it is not used for that purpose and the battery management algorithms will use a different method for calculating battery SOC, such as Coulomb or current integration. It is typically not desirable to use Coulomb integration to determine battery SOC exclusively because it is necessary to have an accurate history of the battery current for the integration and the current sensors typically used for automotive applications for measuring battery current are not accurate enough. Thus, by not knowing an initial current point, error is injected into the calculations which increases over time.

### SUMMARY OF THE INVENTION

In accordance with the teachings of the present invention, a system and method are disclosed for determining whether an onboard estimation process, such as a recursive least squares regression process, can effectively calculate the state-of-charge of a battery. The method includes defining a current sample time and a previous sample time and measuring the battery current. The method then calculates a variation moving average of the measured current and an index of current change rate determined by averaging the absolute value of the current variation moving average using the measured current and calculated moving averages from the previous sample time. The method then determines if the current change index is greater than a predetermined threshold, and if so, the estimate of the battery state-of-charge resulting from the onboard estimation process is valid.

Additional features of the present invention will become apparent from the following description and appended claims, taken in conjunction with the accompanying drawings.

### BRIEF DESCRIPTION OF THE DRAWINGS

FIG. 1 is a simplified plan view of a hybrid vehicle including a battery and a main power source;

FIG. 2 is a flow chart diagram showing the operation of an algorithm for determining whether a battery current is changing at a fast enough rate so that a recursive least squares algorithm can accurately be used to estimate battery SOC; and

FIG. 3 is a block diagram of a system for determining if a battery current is changing with enough excitation so that an estimation algorithm can accurately determine battery SOC.

### DETAILED DESCRIPTION OF THE EMBODIMENTS

The following discussion of the embodiments of the invention directed to a system and method for determining whether an RLS algorithm can effectively be used to estimate battery SOC is merely exemplary in nature, and is no way intended to limit the invention or its applications or uses. For example, the invention has particular application for use in managing a vehicle battery. However, as will be appreciated by those skilled in the art, the technique disclosed herein will have other applications other than vehicle applications.

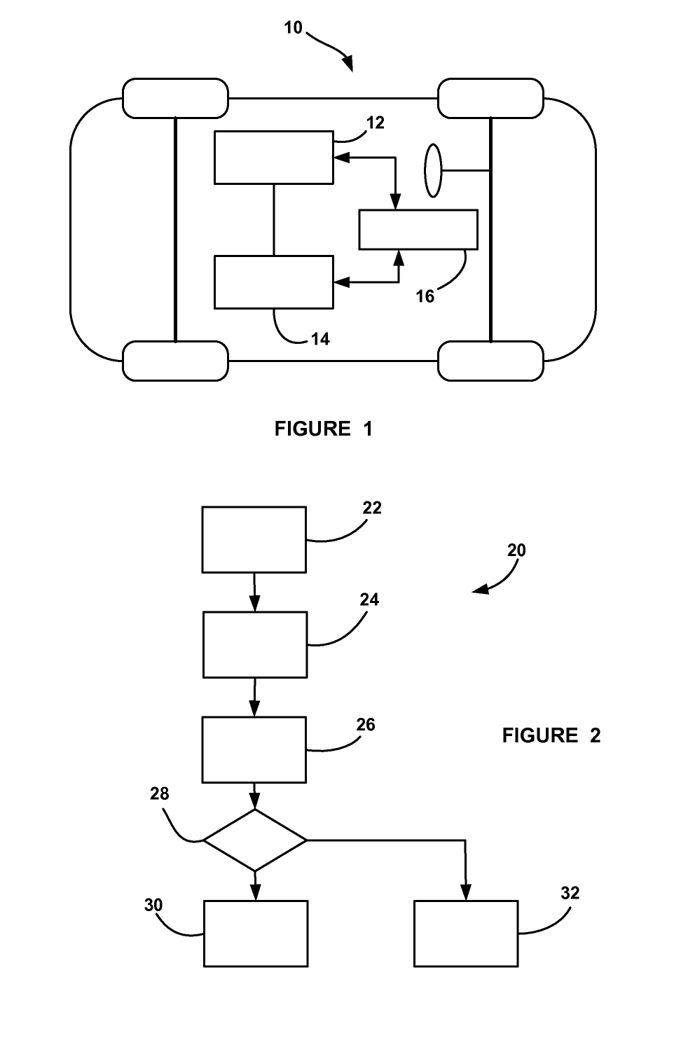

FIG. 1 is a simplified plan view of a vehicle 10 including a high voltage battery 12 and a main power source 14, where the vehicle 10 is intended to represent any hybrid vehicle, such as hybrid internal combustion engine vehicles, fuel cell system vehicle, etc. The battery 12 can be any battery suitable for a hybrid vehicle, such as a lead-acid battery, metal hydride battery, lithium-ion battery, etc. The vehicle 10 is also intended to represent any electric only vehicle that only employs a battery as the power source. The vehicle 10 includes a controller 16 that is intended to represent all of the control modules and devices necessary for the proper operation and control of the power provided by the battery 12 and the power source 14 to drive the vehicle 10, recharge the battery 12 by the power source 14 or regenerative braking, and determine the battery SOC and power capability.

FIG. 2 is a flow chart diagram 20 showing an algorithm for determining whether battery current is changing with enough excitation so that the battery open circuit voltage V_{oc} can be accurately estimated from battery terminal voltage and current using an estimation algorithm, such as the RLS algorithm. At box 22, the algorithm measures the battery current using a current sensor (not shown) and determines a current sample time t. From the current measurement, the algorithm calculates a current variation moving average Im at box 24 using equation (1) below. The current variation moving average Im is an average of the battery current variation over subsequent sampling time instants.

Im(i)=a[Im(i−1)]+I(i)−I(i−1) (1)

Where a is a predetermined coefficient, I(i) is the measured current for the current sample time t, I(i−1) is the measured current from a previous sample time i−1 and Im(i−1) is the calculated current variation moving average from the previous sample time i−1.

The current variation moving average Im(i) is then used to determine an index of current chage rate I_{c} at box 26 using equation (2) below. The index Ic is the average of the absolute value of the current variation moving average Im over subsequent sample time instants.

Ic(i)=b[Ic(i−1)]+(1−b)[Im(i)|] (2)

Where b is a predetermined constant and Ic(i−1) is the moving average of the absolute value of the current variation moving average Im from the last sample time i−1. It should be noted that other types of norm functions than the absolute value can also be applied in equation (2) such as:

Ic(i)=b[Ic(i−1)]+(1−b)[Im²(i)] (3)

The algorithm then determines if the index Ic is above a predetermined threshold at decision diamond 28, and if so, the algorithm uses the recursive least squares (RLS) regression algorithm to estimate battery SOC at box 30 in the known manner, such as disclosed in the '299 application referenced above. The battery open circuit voltage V_{oc} is calculated using the RLS algorithm, and then the battery SOC is determined from a look-up table based on the open circuit voltage V_{oc} and battery temperature T. The RLS algorithm discussed herein employs a regression of the terminal voltage and current to estimate the open circuit voltage (OCV) and the ohmic resistance R, i.e., the high frequency resistance. The battery SOC is then determined from the OCV by the look-up table. The OCV and the potential over the ohmic resistance R are subtracted from the terminal voltage. The remaining voltage is further regressed to obtain other battery parameters.

If the moving average Ic is less than the threshold at the decision diamond 28 the battery current does not contain enough excitation to provide enough information for the RLS algorithm, or other estimation algorithm, to accurately estimate Voc, then Coulomb integration is used at box 32 to determine battery SOC in the known manner.

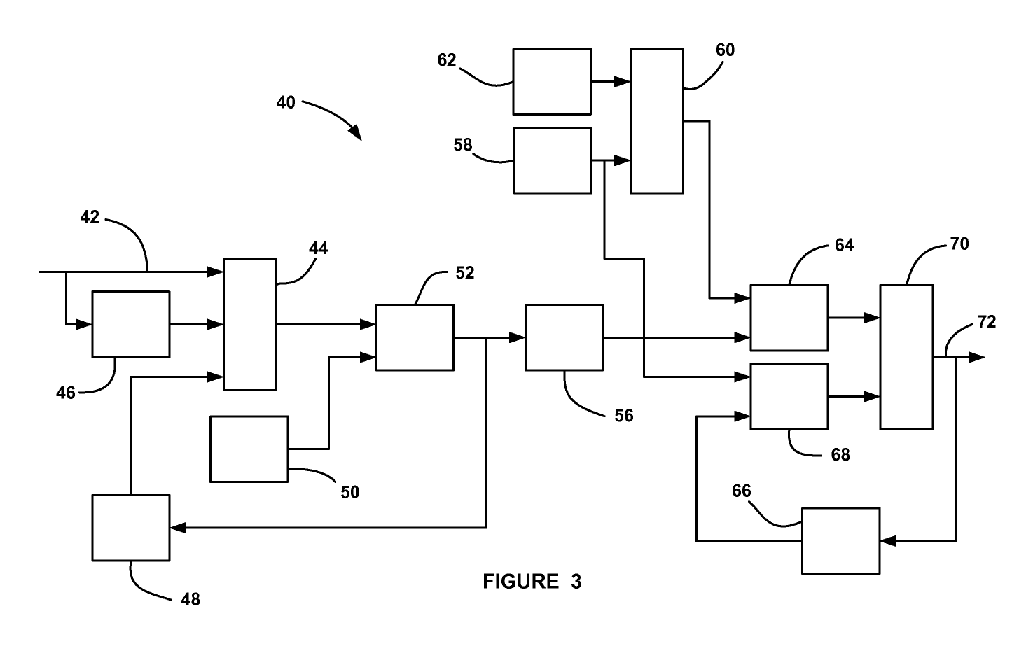

FIG. 3 is a block diagram of a system 40 that determines whether the RLS algorithm, or other estimation algorithm, will be able to provide an accurate battery SOC, as discussed above. The measured battery current I is provided on line 42 to a box 44 that determines the variation moving average Im by equation (1). The measured current I is delayed one sample time t at box 46 and the previous current variation moving average Im(i−1) is provided to the box 44 by delay box 48. The output of the box 44 is multiplied at box 52 by the constant a from box 50, which provides the current variation moving average Im for the current sample time t.

The index Ic of the current variation moving average Im is then calculated by equation (2). The absolute value of the current variation moving average Im is provided at box 56. The constant b is provided by box 58 and the value 1 is provided by box 62 to box 60 that determines the value (1-b). The value (1−b) is multiplied by the absolute value of the current variation moving average Im at box 64, and the delayed moving average Im(i−1) is provided by delay box 66 and is multiplied by the constant b at box 68. The two multiplied values from the boxes 64 and 68 are then added at box 70 to get the index Ic, which is then compared to the threshold as discussed above.

The foregoing discussion discloses and describes merely exemplary embodiments of the present invention. One skilled in the art will readily recognize from such discussion and from the accompanying drawings and claims that various changes, modifications and variations can be made therein without departing from the spirit and scope of the invention as defined in the following claims.

What is claimed is:

1. A method for determining whether a recursive least squares process can effectively be used to calculate state-of-charge (SOC) of a battery, said method comprising:
defining a current sample time and a previous sample time;
measuring a current of the battery;
calculating a current variation moving average of the measured current over subsequent sample times;
calculating a current change index by averaging a norm of the moving average of the current variation over the subsequent sample times;
determining if the current change index is greater than a predetermined threshold; and
using the recursive least squares process to estimate the battery state-of-charge if the current change index is greater than the threshold.

2. The method according to claim 1 wherein calculating the moving average of the measured current variation includes using the equation:
Im(i)=a[Im(i−1)]+I(i)−I(i−1)
where Im is the variation of the moving average, a is a predetermined coefficient, I(i) is the measured current at the current sample time, I(i−1) is the measured current from the previous sample time i−1 and Im(i−1) is the calculated current variation moving average from the previous sample time.

3. The method according to claim 1 wherein calculating the current change index includes using the equation:
Ic(i)=b[Ic(i−1)]+(1−b)[Im(i)]
where Ic is the current change index as the moving average of the absolute value of the current variation moving average, b is a predetermined coefficient and Im is the variation moving average of the current.

4. The method according to claim 1 further comprising using a Coulomb integration process to determine battery state-of-charge if the moving average of the variation moving average of the current is less than the threshold.

5. The method according to claim 1 wherein the battery is a vehicle battery.

6. The method according to claim 5 wherein the vehicle battery is a lithium-ion battery.

7. A method for determining whether a recursive least squares regression process can effectively be used to calculate state-of-charge (SOC) of a vehicle battery, said method comprising:
defining a current sample time and a previous sample time;
measuring a current of the battery;
calculating a current variation moving average of the measured current over subsequent sample times;
calculating a current change index by averaging a norm of the moving average of the current variation over the subsequent sample times;
determining if the current change index is greater than a predetermined threshold;
using the recursive least squares process to estimate the battery state-of-charge if the current change index is greater than the threshold; and
using a Coulomb integration process to determine battery state-of-charge if the moving average of the variation moving average of the current is less than the threshold.

8. The method according to claim 7 wherein calculating the variation moving average of the measured current includes using the equation:
Im(i)=a[Im(i−1)]+I(i)−I(i−1)
where Im is the variation of the moving average, a is a predetermined coefficient, I(i) is the measured current at the current sample time, I(i−1) is the measured current from the previous sample time i−1 and Im(i−1) is the calculated current variation moving average from the previous sample time, and wherein calculating the current change index includes using the equation:
Ic(i)=b[Ic(i−1)]+(1−b)[Im(i)]
where Ic is the moving average of the variation moving average of the current, b is a predetermined coefficient and Im is the variation moving average of the current.

9. The method according to claim 7 wherein the vehicle battery is a lithium-ion battery.

10. A system for determining whether a recursive least squares regression process can effectively be used to calculate state-of-charge (SOC) of a battery, said system comprising:
means for defining a current sample time and a previous sample time;
means for measuring a current of the battery;
means for calculating a current variation moving average of the measured current over subsequent sample times;
means for calculating a current change index by averaging a norm of the moving average of the current variation over the subsequent sample times;
means for determining if the current change index is greater than a predetermined threshold; and
means for using the recursive least squares process to estimate the battery state-of-charge if the current change index is greater than the threshold.

11. The system according to claim 10 wherein the means for calculating the variation moving average of the measured current uses the equation:
Im(i)=a[Im(i−1)]+I(i)−I(i−1)
where Im is the variation of the moving average, a is a predetermined coefficient, I(i) is the measured current at the current sample time, I(i−1) is the measured current from the previous sample time i−1 and Im(i−1) is the calculated current variation moving average from the previous sample time.

12. The system according to claim 10 wherein the means for calculating the moving average uses the equation:
Ic(i)=b[Ic(i−1)]+(1−b)[|Im(i)|]
where Ic is the moving average of the variation moving average of the current, b is a predetermined coefficient and Im is the variation moving average of the current.

13. The system according to claim 10 further comprising means for using a Coulomb integration process to determine battery state-of-charge if the moving average of the variation moving average of the current is less than the threshold.

14. The system according to claim 10 wherein the battery is a vehicle battery.

15. The system according to claim 14 wherein the vehicle battery is a lithium-ion battery.
